(19) United States
(12) Patent Application Publication
(10) Pub. No.: US 2008/0062800 A1
(43) Pub. Date: Mar. 13, 2008

(54) Semiconductor memory device

(75) Inventor: Sung-Soo Chi, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,693

(22) Filed: Dec. 29, 2006

(30) Foreign Application Priority Data
Aug. 31, 2006 (KR) 2006-0083530

(51) Int. Cl. G11C 5/14

(52) U.S. Cl. 365/226

(57) ABSTRACT

A semiconductor memory device includes: a high voltage input pad for receiving a high voltage which has the highest voltage level among a plurality of voltages used for a data access operation; a core region for storing a plurality of data; a peripheral region including a circuit for accessing the data stored in the core region; a high voltage transfer unit for supplying the high voltage inputted through the high voltage input pad to at least one of the core region and the peripheral region; a core voltage generation unit for generating at least one first driving voltage used in the core region by using the high voltage; and a peripheral region voltage generation unit for generating at least one second driving voltage used in the peripheral region by using the high voltage.

### CROSS-REFERENCE TO RELATED APPLICATION

The present invention claims priority of Korean patent application number 10-2006-0083530, filed on Aug. 31, 2006, which is incorporated by reference in its entirety.

### BACKGROUND OF THE INVENTION

The present invention relates to a semiconductor memory device; and, more particularly, to an internal voltage supply circuit for use in a semiconductor memory device.

A semiconductor memory device is a semiconductor device for storing data and reading the stored data. For effectively storing and reading data, the semiconductor memory device generates various internal voltages needed for an internal operation by using an externally inputted power supply voltage and a ground voltage.

The internal voltage includes a core voltage used in a core region where a plurality of data are stored; a peripheral region driving voltage used in a peripheral region where various circuits are disposed in order to output data stored in the core region or input data to the core region; and a high voltage and a low voltage used for effectively controlling a metal oxide semiconductor (MOS) transistor included in the core region.

Herein, the high voltage has a higher voltage level than the power supply voltage by a constant voltage level. The high voltage is mainly supplied to a gate of the MOS transistor included in the core region. The low voltage has a lower voltage level than the ground voltage by a constant voltage level. The low voltage is mainly used as a bulk voltage of the MOS transistor included in the core region.

FIG. 1 is a block diagram showing a conventional semiconductor memory device.

As shown, the conventional semiconductor memory device includes a high voltage generation unit 10, a word line driver 20, a core voltage generation unit 30, a core region 40, a peripheral region 50 and a data input/output driver 60.

The high voltage generation unit 10 receives a power supply voltage VDD in order to generate a high voltage VPP whose voltage level is higher than that of the power supply voltage VDD. The word line driver 20 receives the high voltage VPP in order to generate a word line driving voltage WL and output the word line driving voltage WL to the core region 30.

The core voltage generation unit 30 receives the power supply voltage VDD in order to generate a core voltage VCORE whose voltage level is lower than that of the power supply voltage VDD and output the core voltage VCORE to the core region 40. The peripheral region 50 receives the power supply voltage VDD in order to transfer a data received from the core region 40 to the data input/output driver 60 or transfer a data received from the data input/output driver 60 to the core region 50.

The core region 40 includes a plurality of unit cells. Each unit cell generally includes a storing medium for storing a data and a MOS transistor used as a switch for connecting the storing medium to a data transfer line in order to transfer a data. Herein, an n-type metal oxide semiconductor (NMOS) transistor is used as the switching MOS transistor since the NMOS transistor has a smaller size than a p-type metal oxide semiconductor (PMOS) transistor so that the NMOS transistor has an advantage over the PMOS transistor in an aspect of integration.

However, due to the characteristics of the NMOS transistor, an amount of a threshold voltage of the MOS transistor is lost during transferring a high level data signal. For solving this problem, the conventional semiconductor memory device generates the high voltage VPP whose voltage level is higher than that of the power supply voltage VDD by a voltage level of the threshold voltage, and the generated high voltage VPP is supplied to a gate of the NMOS transistor. Therefore, for this purpose, the conventional semiconductor memory device should include a high voltage generation circuit.

FIG. 2A is a block diagram depicting the high voltage generation unit 10 shown in FIG. 1.

As shown, the high voltage generation unit 10 includes a level detection unit 11, a ring oscillator 12 and a high voltage pump circuit 13.

The level detection unit 11 serves to detect a voltage level of the high voltage VPP. The ring oscillator 12 generates oscillation control signals PL, PR, GL and GR according to a detection result of the level detection unit 11. The high voltage pump circuit 13 generates the high voltage VPP in response to the oscillation control signals PL, PR, GL and GR.

FIG. 2B is a schematic circuit diagram illustrating the high voltage pump circuit 13 shown in FIG. 2A.

As shown, the high voltage pump circuit 13 includes a plurality of MOS transistors for receiving the oscillation control signals PL, PR, GL and GR in order to generate the high voltage VPP.

FIG. 2C is a wave diagram showing an operation of the high voltage pump circuit 13 shown in FIG. 2B.

While the power supply voltage supplied to a semiconductor memory device is required to be decreased for reducing power consumption, the high voltage requires a voltage level which is higher than or equal to a particular voltage level for effectively turning on a MOS transistor included in the core region.

Formerly, it was satisfactory that the high voltage has a voltage level which is about 1.5 times higher than that of the power supply voltage. However, as a voltage level of the power supply voltage has been decreased recently, the high voltage should have a voltage level which is about 2 or 3 times higher than that of the power supply voltage.

Therefore, it is more difficult for the semiconductor memory device to generate the high voltage by using the power supply voltage as a voltage level of the power supply voltage is decreased. Further, the semiconductor memory device consumes too much power in order to generate the high voltage, and a circuit for generating the high voltage is more complicated and has a larger size.

### SUMMARY OF THE INVENTION

Embodiments of the present invention are directed to provide a semiconductor memory device for directly receiving a high voltage needed for accessing data without an internal high voltage generation circuit.

In accordance with an aspect of the present invention, there is provided a semiconductor memory device, including: a high voltage input pad for receiving a high voltage which has the highest voltage level among a plurality of voltages used for a data access operation; a core region for storing a plurality of data; a peripheral region including a circuit for accessing the data stored in the core region; a high voltage transfer unit for supplying the high voltage inputted through the high voltage input pad to at least one of the core region and the peripheral region; a core voltage generation unit for generating at least one first driving voltage used in the core region by using the high voltage; and a peripheral region voltage generation unit for generating at least one second driving voltage used in the peripheral region by using the high voltage.

In accordance with another aspect of the present invention, there is provided a method for operating a semiconductor memory device, including the steps of: receiving a high voltage which has the highest voltage level among a plurality of voltages used for a data access operation; generating a core voltage by decreasing the high voltage; outputting a data signal of a core region by using the high voltage and the core voltage; generating a driving voltage which has a voltage level of a power supply voltage by decreasing the high voltage; and outputting data signal of the core region by using the high voltage and the driving voltage.

In accordance with a further aspect of the present invention, there is provided a semiconductor memory device, including: a high voltage input pad for receiving a high voltage which has the highest voltage level among a plurality of voltages used for a data access operation; a core region which includes a plurality of word lines, a plurality of bit lines and an plurality of sense amplifiers, wherein the sense amplifier amplifies a data signal corresponding to the word line through the bit line; a high voltage transfer unit for supplying the high voltage inputted through the high voltage input pad to the word line included in the core region; and a core voltage generation unit for generating a core voltage used by the sense amplifier to amplify a signal transferred to the bit line by decreasing the high voltage.

In accordance with a further aspect of the present invention, there is provided a semiconductor memory device, including: a unit cell which includes a storing medium for storing a data signal and an NMOS transistor as a switch for transferring the data signal; a high voltage transfer unit for externally receiving a high voltage in order to supply the high voltage to a gate of the NMOS transistor, wherein a voltage level of the high voltage is the sum of a voltage level of a driving voltage supplied to one terminal of the NMOS transistor and a voltage level of a threshold voltage of the NMOS transistor; and a driving voltage generation unit for generating the driving voltage by decreasing the high voltage.

### BRIEF DESCRIPTION OF THE DRAWINGS

FIG. 1 is a block diagram showing a conventional semiconductor memory device.

FIG. 2A is a block diagram depicting the high voltage generation unit shown in FIG. 1.

FIG. 2B is a schematic circuit diagram illustrating the high voltage pump circuit shown in FIG. 2A.

FIG. 2C is a wave diagram showing an operation of the high voltage pump circuit shown in FIG. 2B.

FIG. 3 is a block diagram showing the semiconductor memory device in accordance with the preferred embodiment of the present invention.

FIG. 4 is a schematic circuit diagram depicting a word line decoder included in the core region shown in FIG. 3.

FIG. 5 is a schematic circuit diagram illustrating the core voltage generation unit shown in FIG. 3.

FIG. 6 is a schematic circuit diagram showing the core region shown in FIG. 3.

FIG. 7 is a schematic circuit diagram showing the data input/output driver shown in FIG. 3.

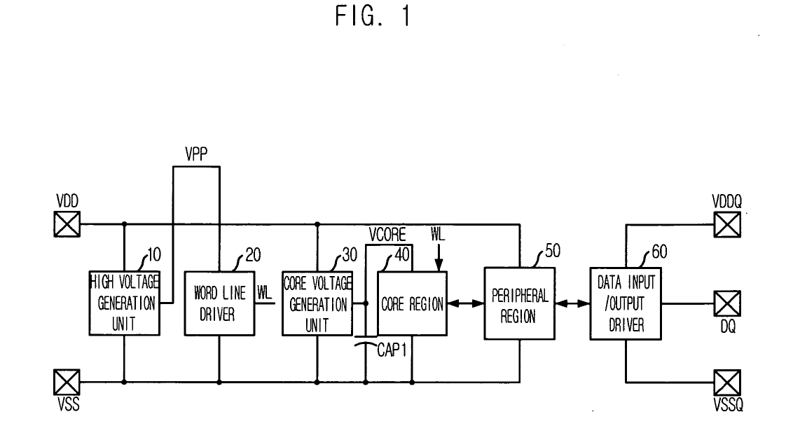

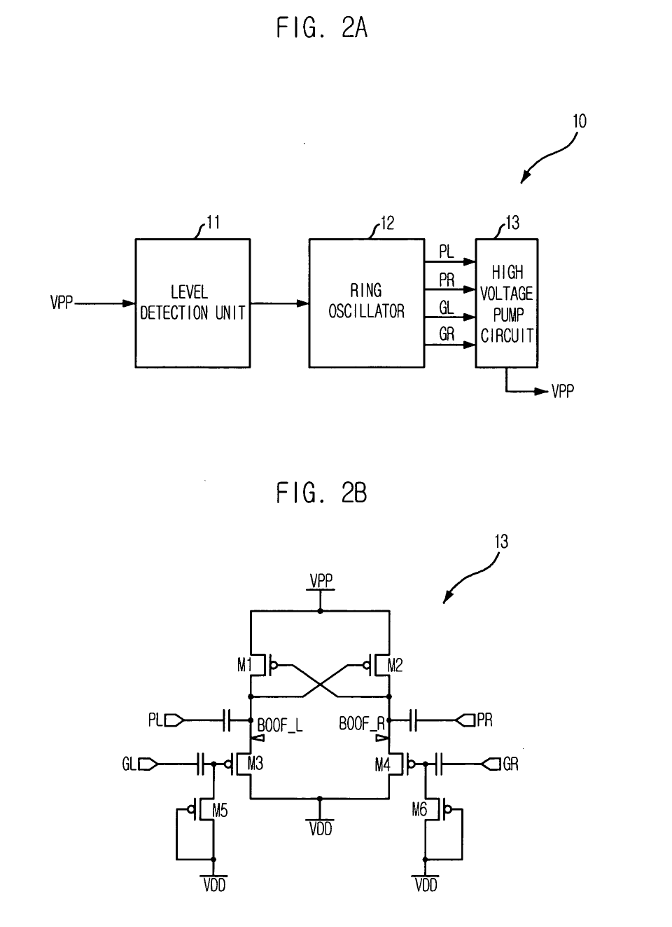

### DESCRIPTION OF SPECIFIC EMBODIMENTS

It is an object of the present invention to provide a semiconductor memory device for directly receiving a high voltage needed for accessing data without an internal high voltage generation circuit. Therefore, since a high voltage generation circuit is not included in the semiconductor memory device, a size of the semiconductor memory device can be reduced. Further, even if the semiconductor memory device is operated at a low power supply voltage, a high voltage whose voltage level is 2 or 3 times higher that that of the power supply voltage is not needed to be generated and, thus, an operational reliability of the semiconductor memory device is improved. Further, a power consumption of the semiconductor memory device can be reduced.

Hereinafter, a semiconductor memory device in accordance with the present invention will be described in detail referring to the accompanying drawings.

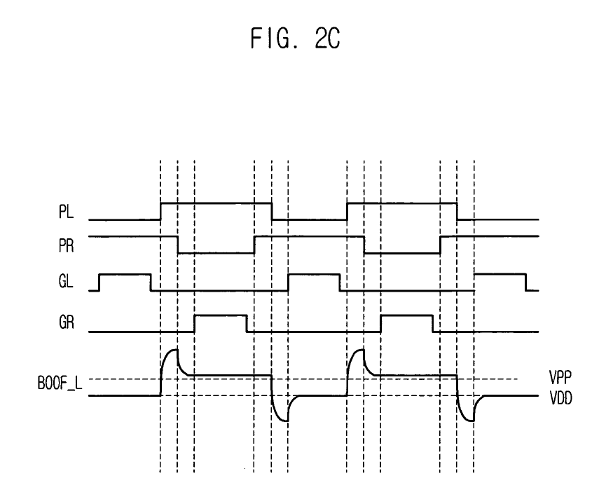

FIG. 3 is a block diagram showing the semiconductor memory device in accordance with the preferred embodiment of the present invention.

Referring to FIG. 3, the semiconductor memory device includes a high voltage input pad VPP_PAD, a high voltage transfer unit 100, a core voltage generation unit 200, a core region 300, a peripheral region voltage generation unit 400, a peripheral region 500, a data input/output driver 600, a ground voltage input pad VSS_PAD, a data input/output pad DQ, an input/output voltage input pad VDDQ_PAD and an input/output ground voltage input pad VSSQ_PAD.

The high voltage input pad VPP_PAD receives a highest voltage among a plurality of voltages used for accessing data. For instance, the semiconductor memory device requires a high voltage VPP, a core voltage VCORE, a bit line precharge voltage VBLP, a cell plate voltage VCP and a low voltage VBB for a data access. Among these voltages, the high voltage VPP has the highest voltage level and the semiconductor memory device receives the high voltage VPP through the high voltage input pad VPP_PAD.

The high voltage transfer unit 100 transfers the high voltage VPP inputted through the high voltage input pad VPP_PAD corresponding to an operation of the core region 300 which requires a high voltage level.

In detail, the high voltage transfer unit 100 generates a word line driving voltage WLP for driving a plurality of word lines included in the core region 300 and an overdriving voltage PP for the core region 300 to perform an overdriving operation. Herein, although it is exemplified that the high voltage transfer unit 100 supplies the core region 300 with a high voltage level driving voltage, the high voltage level driving voltage can be supplied to the peripheral region 500 when the peripheral region 500 requires the high voltage level driving voltage.

The core voltage generation unit 200 generates a core voltage VCORE by decreasing the high voltage VPP and outputs the core voltage VCORE to the core region 300. The core region 300 includes a plurality of unit cells for storing a plurality of data.

The core region 300 needs various driving voltages in order to output stored data to the peripheral region 300 or store data received from the peripheral region 300. Herein, it is illustrated that the core voltage generation unit 200 outputs the core voltage VCORE to the core region 300, and another block for generating other needed driving voltages, e.g., a bit line precharge voltage VBLP, is omitted.

The peripheral region voltage generation unit 400 generates a power supply voltage VDD by decreasing the high voltage VPP and supplies the peripheral region 500 with the power supply voltage VDD. The peripheral region 500 includes various circuits for performing a data access operation.

Herein, the power supply voltage VDD generated by the peripheral region voltage generation unit 400 has the same voltage level as an external power supply voltage a semiconductor memory device typically receives.

As above-mentioned, a semiconductor memory device generally receives the power supply voltage VDD in order to generate various driving voltages needed for the core region 300 including the high voltage VPP which is higher than the power supply voltage VDD. Therefore, a semiconductor memory device had to include a high voltage generation circuit for generating the high voltage VPP.

However, in accordance with the preferred embodiment of the present invention, the semiconductor memory device does not externally receive the power supply voltage but externally receives the highest voltage among all the driving voltages needed for a data access operation. Therefore, the semiconductor memory device in accordance with the preferred embodiment of the present invention does not include the high voltage generation circuit. The semiconductor memory device just includes a transfer circuit for transferring the externally received high voltage to another block which needs the high voltage.

Each of the plurality of unit cells included in the core region 300 includes a storing medium for storing a data signal and an NMOS transistor as a switch for transferring the stored data signal to a bit line. A gate of the NMOS transistor is connected to a word line. The word line is supplied with the word line driving voltage WLP received from the high voltage transfer unit 100. Therefore, a data loss of a high level data due to the NMOS transistor can be prevented.

Meanwhile, the semiconductor memory device performs the overdriving operation in order to sense and amplify the data signal stored in the unit cell at a higher speed. According to the overdriving operation, a higher voltage than the core voltage is supplied at an initial step of the sensing and amplifying operation. The overdriving voltage PP generated by the high voltage transfer unit 100 is supplied to a sense amplifier which senses and amplifies the data signal stored in the unit cell when the overdriving operation is performed.

The data input/output driver 600 receives the input/output voltages VDDQ and VSSQ through the input/output voltage input pad VDDQ_PAD and the input/output ground voltage input pad VSSQ_PAD respectively in order to output a data signal transferred from the peripheral region 500 through the data input/output pad DQ or transfer a data signal inputted through the data input/output pad DQ to the peripheral region 500. That is, a special driving voltage is supplied to the data input/output circuit so that a noise due to a variation of the power supply voltage can be reduced and a driving strength can be improved. Further, the semiconductor memory device can be connected to other devices.

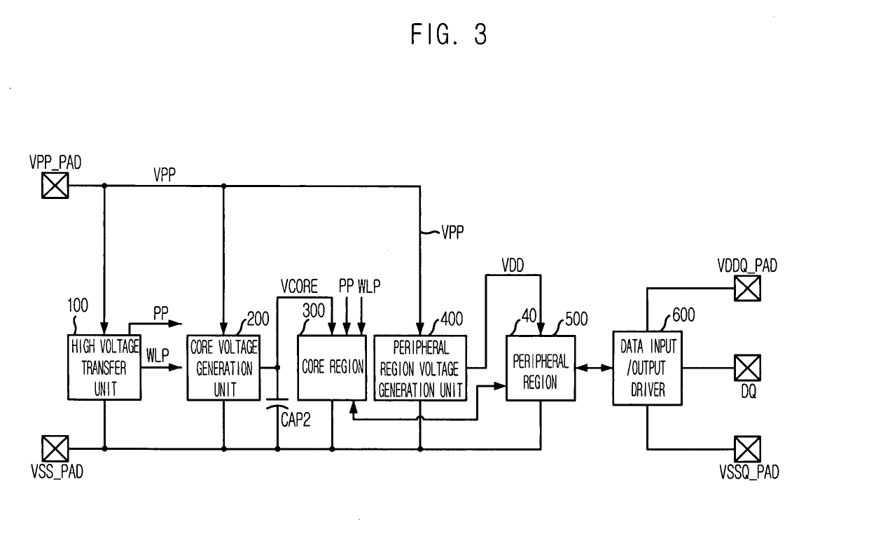

FIG. 4 is a schematic circuit diagram depicting a word line decoder included in the core region 300 shown in FIG. 3.

As shown, the word line decoder receives the word line driving voltage WLP which has a high voltage level and generates a decoded word line activation signal WL in response to a plurality of input signals WLPOFFb, BAX01 and BAX02. For this operation, the word line decoder includes a plurality of MOS transistors M7 to M13 and a plurality of inverters I1 to I3.

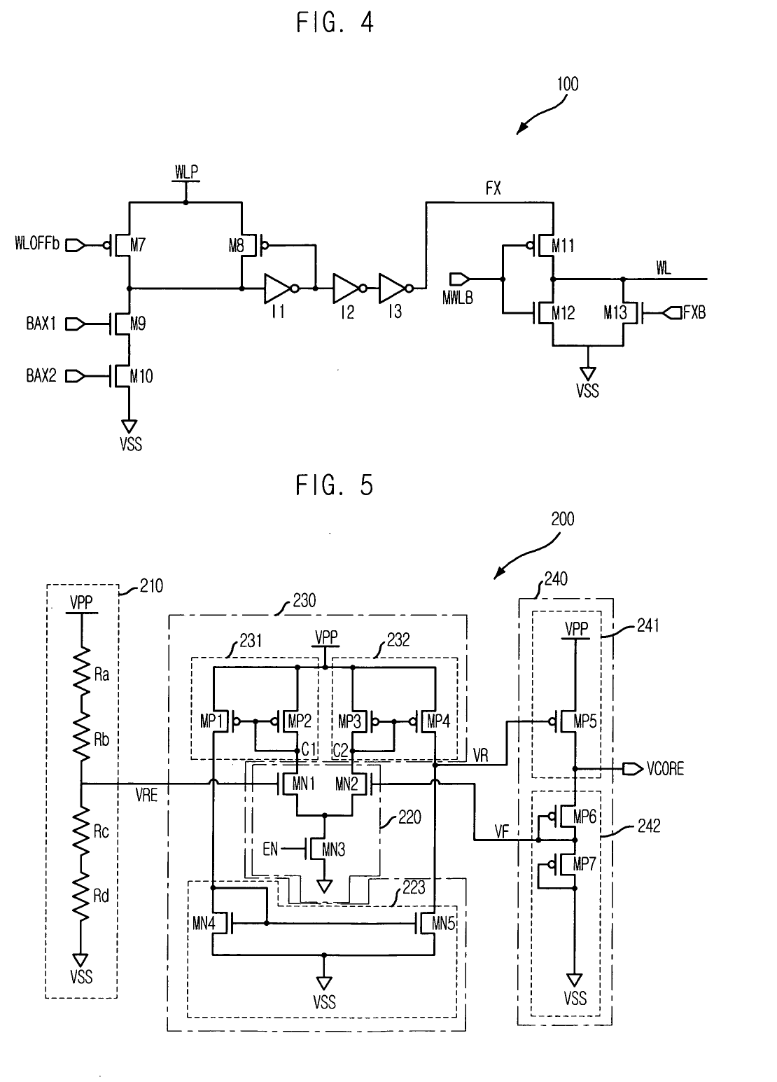

FIG. 5 is a schematic circuit diagram illustrating the core voltage generation unit 200 shown in FIG. 3.

As shown, the core voltage generation unit 200 includes a reference voltage generation unit 210, a voltage comparison unit 220, a comparison result transfer unit 230 and a driving voltage output unit 240.

The reference voltage generation unit 210 generates a reference signal VRE corresponding to a voltage level of the high voltage VPP. The voltage comparison unit 220 compares the reference signal VRE with a feedback signal VF and changes comparison signals C1 and C2 according to the comparison result.

The comparison result transfer unit 230, according to the comparison result, outputs a result signal VR to the driving voltage output unit 240 corresponding to the comparison signals C1 and C2. The driving voltage output unit 240 outputs the feedback signal VF and the core voltage VCORE in response to the result signal VR.

The reference voltage generation unit 210 divides the high voltage VPP by using included resistors Ra, Rb, Rc and Rd in order to generate the reference signal VRE. Herein, a various kinds of voltages, e.g., the core voltage VCORE, can be input to the reference voltage generation unit 210 instead of the high voltage VPP. The voltage comparison unit 220 compares a voltage level of the reference signal VRE with that of the feedback signal VF in order to adjust current amount of the comparison signals C1 and C2 according to the comparison result.

The comparison result transfer unit 230 provides the comparison signals C1 and C2 which have a same current amount to the voltage comparison unit 220 and generates the result signal VR according to the comparison signals C1 and C2 whose current amount are changed by the voltage comparison unit 220. The driving voltage output unit 240 generates the core voltage VCORE and the feedback signal VF according to the result signal VR.

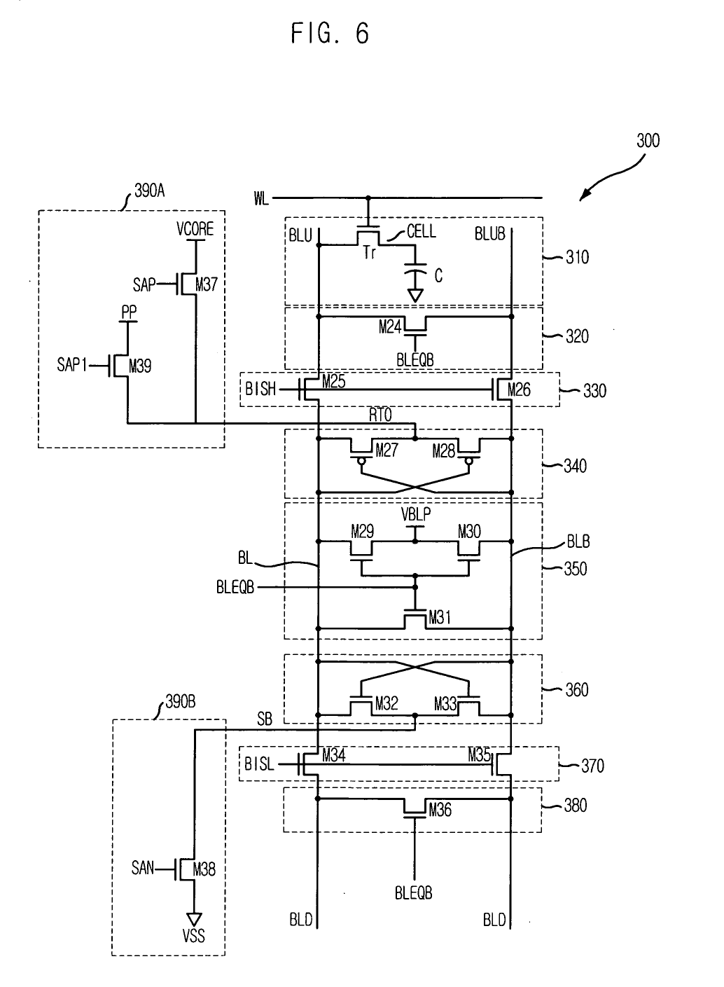

FIG. 6 is a schematic circuit diagram showing the core region 300 shown in FIG. 3. Particularly, a bit line sense amplifying unit is illustrated in detail.

Referring to FIG. 6, the core region 300 includes a unit cell (CELL), a precharge unit 320, a connection unit 330, bit lines sense amplifiers 340 and 360, a precharge unit 350, a connection unit 370, a precharge unit 380 and sense amplifier driving voltage supply units 390A and 390B.

The unit cell includes an NMOS transistor Tr whose gate is coupled to the word line WL and a capacitor C for storing a data signal. The precharge unit 320 includes a MOS transistor M24 for equalizing each voltage level of bit lines BLU and BLUB. The connection unit 330 serves to connect bit lines BL and BLB to the bit lines BLU and BLUB.

The bit line sense amplifier 340 amplifies one of the bit lines BL and BLB whose voltage level is higher than the other to the core voltage VCORE. The bit line sense amplifier 360 amplifies one of the bit lines BL and BLB whose voltage level is lower than the other to a ground voltage VSS.

The precharge unit 350 keeps voltage levels of the bit lines BL and BLB as a precharge voltage VBLP. The connection unit 370 connects the bit lines BL and BLB to bit lines BLD and BLDB. The precharge unit 380 includes a MOS transistor M36 for equalizing each voltage level of the bit lines BLD and BLDB.

The sense amplifier driving voltage supply unit 390A supplies the core voltage VCORE to the sense amplifier 340. The sense amplifier driving voltage supply unit 390B supplies the ground voltage VSS to the sense amplifier 360.

For reducing a size of the semiconductor memory device, a sense amplifier is shared by neighboring two cell blocks. The connection units 320 and 370 serve to connect a sense amplifier to one of two neighboring cell blocks.

The word line driving voltage WLP generated by the high voltage transfer unit 100 is transferred to the word line WL. A gate of the NMOS transistor Tr is supplied with the word line driving voltage WLP which keeps a high voltage level.

Since a core voltage level is supplied to the bit line BLU coupled to one terminal of the NMOS transistor Tr, a data loss does not occur when the NMOS transistor Tr transfers a high level signal from the bit line BLU to the capacitor C or from the capacitor C to the bit line BLU. Therefore, when the semiconductor memory device receives the high voltage only for compensating a high level data loss due to the NMOS transistor Tr, it is sufficient that a voltage level of the high voltage is the sum of a voltage level of the core voltage VCORE inputted to one terminal of the NMOS transistor Tr and a voltage level of a threshold voltage of the NMOS transistor.

Further, when the high voltage VPP is inputted as control signals BISH and BISL which are inputted to gates of MOS transistors M25, M26, M34 and M35 included in the connection units 330 and 370, a signal loss of a high data transferred by the MOS transistors M25, M26, M34 and M35 can be prevented.

Further, the sense amplifiers 340 and 360 perform the overdriving operation temporarily receiving a higher voltage than the core voltage VCORE in order to sense a voltage level of a bit line after the data signal stored in the capacitor C is transferred to the bit line BL. For the overdriving operation, the overdriving voltage PP is supplied to the sense amplifier 340 through a MOS transistor M39 during the overdriving operation.

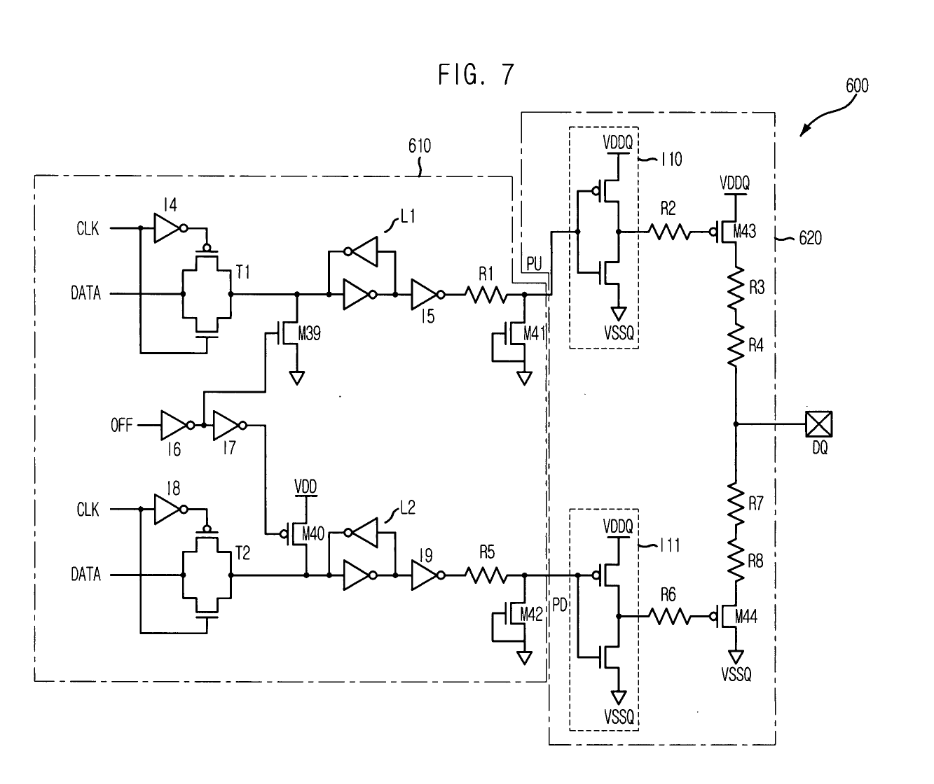

FIG. 7 is a schematic circuit diagram showing the data input/output driver 600 shown in FIG. 3. Particularly, a circuit for outputting data is illustrated in detail.

As shown, the data input/output driver 600 includes a data transfer unit 610 and a data driver 620.

The data transfer unit 610 receives and latches a data (DATA) received from the peripheral region 500 in synchronization with a clock signal in order to output the data to the data driver 620. For this operation, the data transfer unit 610 includes inverters I4 to I9, latches L1 and L2, transfer gates T1 and T2, resistors R1 and R2 and MOS transistors M41 and M42.

The data driver 620 pulls up or pulls down a data output line coupled to the data input/output pad DQ according to the data received from the data transfer unit 610.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device, comprising:
a high voltage input pad for receiving a high voltage which has the highest voltage level among a plurality of voltages used in a semiconductor memory device;
a core region for storing a plurality of data;
a peripheral region including a circuit for accessing the data stored in the core region;
a high voltage transfer unit for supplying the high voltage received by the high voltage input pad to at least one of the core region and the peripheral region;
a core voltage generation unit for generating at least one first driving voltage used in the core region by using the high voltage; and
a peripheral region voltage generation unit for generating at least one second driving voltage used in the peripheral region by using the high voltage.

2. The semiconductor memory device as recited in claim 1, wherein the high voltage is supplied for driving a word line included in the core region.

3. The semiconductor memory device as recited in claim 1, wherein the high voltage is supplied for an overdriving operation of the core region.

4. The semiconductor memory device as recited in claim 1, wherein the second driving voltage has a voltage level of a power supply voltage.

5. The semiconductor memory device as recited in claim 1, wherein the core voltage generation unit includes:
a reference voltage generation unit for generating a reference signal;
a voltage comparison unit for comparing the reference signal with a feedback signal;
a comparison result transfer unit for generating a result signal which corresponds to a variation amount of a comparison signal inputted to the voltage comparison unit according to a comparison result of the voltage comparison unit; and
a driving voltage output unit for generating the feedback signal and the at least one first driving voltage according to the result signal.

6. The semiconductor memory device as recited in claim 1, wherein the core region includes:
a first cell block provided with a plurality of first unit cells;
a second cell block provided with a plurality of second unit cells;
a bit line sense amplifier for sensing and amplifying a data signal stored in the first unit cell or a data signal stored in the second unit cell;
a first MOS transistor for connecting the bit line sense amplifier to the first unit cell; and
a second MOS transistor for connecting the bit line sense amplifier to the second unit cell,
wherein the high voltage is supplied to each gate of the first and the second MOS transistors.

7. The semiconductor memory device as recited in claim 1, wherein a voltage level of the high voltage is the sum of a voltage level of a driving voltage supplied to one terminal of an NMOS transistor included in the core region and a voltage level of a threshold voltage of the NMOS transistor.

8. The semiconductor memory device as recited in claim 1, further comprising:
an output voltage input pad for receiving an output voltage in order to output data; and
a data output driver for outputting a data signal from the peripheral region by using the output voltage.

9. A method for operating a semiconductor memory device, comprising the steps of:
receiving a high voltage which has the highest voltage level among a plurality of voltages used for a data access operation;
generating a core voltage by decreasing the high voltage;
outputting a data signal of a core region by using the high voltage and the core voltage;
generating a driving voltage which has a voltage level of a power supply voltage by decreasing the high voltage; and
outputting data signal of the core region by using the high voltage and the driving voltage.

10. The method as recited in claim 9, further comprising the steps of:
transferring an input data signal which is inputted to the core region by using the driving voltage; and
storing the input data signal to the core region by using the high voltage and the core voltage.

11. The method as recited in claim 9, wherein the high voltage is supplied for driving a word line included in the core region.

12. The method as recited in claim 9, wherein the high voltage is supplied for an overdriving operation of the core region.

13. The method as recited in claim 9, wherein a voltage level of the high voltage is the sum of a voltage level of a driving voltage supplied to one terminal of an NMOS transistor included in the core region and a voltage level of a threshold voltage of the NMOS transistor.

14. A semiconductor memory device, comprising:
a high voltage input pad for receiving a high voltage which has the highest voltage level among a plurality of voltages used for a data access operation;
a core region which includes a plurality of word lines, a plurality of bit lines and a plurality of sense amplifiers, wherein the sense amplifiers each amplify a data signal corresponding to the word lines through the bit lines;
a high voltage transfer unit for supplying the high voltage inputted through the high voltage input pad to the word line included in the core region; and
a core voltage generation unit for generating a core voltage used for the sense amplifier to amplify a signal transferred to the bit line by decreasing the high voltage.

15. The semiconductor memory device as recited in claim 14, further comprising:
a peripheral region including a circuit for accessing the data stored in the core region; and
a peripheral region voltage generation unit for generating a driving voltage used in the peripheral region by decreasing the high voltage.

16. The semiconductor memory device as recited in claim 14, wherein the high voltage is supplied for an overdriving operation of the core region.

17. The semiconductor memory device as recited in claim 14, wherein a voltage level of the high voltage is the sum of a voltage level of a driving voltage supplied to one terminal of an NMOS transistor included in a unit cell coupled to the word line and a voltage level of a threshold voltage of the NMOS transistor.

18. A semiconductor memory device, comprising:
a unit cell which includes a storing medium for storing a data signal and an NMOS transistor as a switch for transferring the data signal;
a high voltage transfer unit for externally receiving a high voltage in order to supply the high voltage to a gate of the NMOS transistor, wherein a voltage level of the high voltage is the sum of a voltage level of a driving voltage supplied to one terminal of the NMOS transistor and a voltage level of a threshold voltage of the NMOS transistor; and
a driving voltage generation unit for generating the driving voltage by decreasing the high voltage.

19. The semiconductor memory device as recited in claim 18, wherein the driving voltage generation unit includes:
a reference voltage generation unit for generating a reference signal;
a voltage comparison unit for comparing the reference signal with a feedback signal;
a comparison result transfer unit for generating a result signal which corresponds to a variation amount of a comparison signal inputted to the voltage comparison unit according to the comparison result of the voltage comparison unit; and
a driving voltage output unit for generating the feedback signal and the driving voltage according to the result signal.
